(19) United States
(12) Patent Application Publication
(10) Pub. No.: US 2015/0102300 A1
(43) Pub. Date: Apr. 16, 2015

(54) ORGANIC LIGHT EMITTING DISPLAY APPARATUS AND METHOD OF MANUFACTURING THE SAME

(71) Applicant: SAMSUNG DISPLAY CO., LTD., Yongin-City (KR)

(72) Inventor: Su-Cheol GONG, Yongin-City (KR)

(73) Assignee: SAMSUNG DISPLAY CO., LTD., Yongin-City (KR)

(21) Appl. No.: 14/294,200

(22) Filed: Jun. 3, 2014

(30) Foreign Application Priority Data
Oct. 11, 2013 (KR) 10-2013-0121503

(51) Int. Cl. H01L 51/52; H01L 51/56; H01L 27/32

(52) U.S. Cl. CPC H01L 51/5246; H01L 27/3244; H01L 51/56
USPC 257/40; 438/28

(57) ABSTRACT

An organic light-emitting display apparatus and a method of manufacturing the organic light-emitting display apparatus is provided. The organic light-emitting display apparatus may include a first substrate including a display portion, a second substrate disposed opposite the first substrate, a sealing line that encloses the display portion and binds the first substrate to the second substrate; and a plurality of sealing branches binding the first substrate to the second substrate in which one end of each of the plurality of sealing branches contacts the sealing line and another end of each of the plurality of sealing branches does not contact the sealing line.

### CROSS-REFERENCE TO RELATED APPLICATION

Korean Patent Application No. 10-2013-0121503, filed on Oct. 11, 2013, in the Korean Intellectual Property Office, and entitled: “Organic Light Emitting Display Apparatus And Method Of Manufacturing The Same,” is incorporated by reference herein in its entirety.

### BACKGROUND

1. Field

One or more embodiments relate to organic light-emitting display apparatuses and methods of manufacturing the same.

2. Description of the Related Art

A display apparatus provides visual information such as images or videos and can be manufactured in various ways.

More particularly, an organic light-emitting display apparatus is a self-light-emitting display apparatus that emits light by electrical excitation of organic compounds. Thus, organic light-emitting display apparatuses may be drivable at low voltages, may be easily thinned, may have wide viewing angles, and may have short response times. Accordingly, organic light-emitting display apparatuses have received much attention as next generation displays.

### SUMMARY

Exemplary embodiments may provide an organic light-emitting display apparatus including a first substrate including a display portion, a second substrate opposite the first substrate, a sealing line enclosing the display portion and binding the first substrate to the second substrate, and a plurality of sealing branches binding the first substrate to the second substrate. The plurality of sealing branches may each include a first end and a second end. Each first end may contact the sealing line, and each second end may not contact the sealing line. In exemplary embodiments, each second end is externally exposed.

The plurality of sealing branches may be separated from each other.

The organic light-emitting apparatus may include a stiffener between two neighboring sealing branches of the plurality of sealing branches and the stiffener may supplement binding between the sealing branches. The stiffener may include a polymer resin.

At least one sealing branch of the plurality of sealing branches may perpendicularly contact the sealing line.

At least one of the plurality of sealing branches may have a uniform width or at least one of the plurality of sealing branches may have a non-uniform width.

At least one of the plurality of sealing branches may include a crack preventing portion configured to prevent a crack generated in the first end from spreading to the second end.

At least one of the plurality of sealing branches may include a first sealing branch that may contact the sealing line at a first end of the first sealing branch and may contact the crack preventing portion at a second end of the first sealing branch. At least one of the plurality of sealing branches may also include a second sealing branch that may contact the crack preventing portion at a first end of the second sealing branch and may be externally exposed at a second end of the second sealing branch.

At least one of the first and the second sealing branches may include an area that has a narrower width than a maximum width of the crack preventing portion. At least one of the first and the second sealing branches may have the narrowest width in an area that contacts the crack preventing portion.

The sealing line and the plurality of sealing branches may include the same material, and the materials may include glass frit.

The first substrate may further include a peripheral area that may enclose the display portion. An insulating layer may be over the display portion and the peripheral area on the first substrate, and the insulating layer may include at least one through-hole corresponding to the peripheral area.

The sealing line may fill inside a first through-hole.

The display portion may include a buffer layer, a gate insulating film, and an interlayer insulating layer. The insulating layer may include at least one of the buffer layer, the gate insulating film, and the interlayer insulating layer.

A metal layer may be in the insulating layer and may include at least one second through-hole on the first substrate. The first through-hole may be in the second through-hole.

Exemplary embodiments also provide a method of manufacturing an organic light-emitting display apparatus including providing a first mother substrate comprising a plurality of display portions, forming a plurality of sealing lines respectively enclosing a plurality of display portions and a plurality of sealing bridges connecting neighboring sealing lines among the plurality of sealing lines, binding the first mother substrate to the second mother substrate with the plurality of sealing lines and the plurality of sealing bridges; and cutting the plurality of sealing bridges to separate the plurality of display portions.

### BRIEF DESCRIPTION OF THE DRAWINGS

Features will become apparent to those of ordinary skill in the art by describing in detail exemplary embodiments with reference to the attached drawings in which:

FIG. 1 illustrates a plane view of an organic light-emitting display apparatus according to an embodiment;

FIG. 2A illustrates a cross-sectional view of I-I of FIG. 1;

FIG. 2B illustrates a cross-sectional view of II-II of FIG. 1;

FIG. 3A to FIG. 3B illustrate plane views showing shapes of a sealing branch shown in FIG. 1;

FIG. 4 illustrates a sealing line and a display portion shown in FIG. 1;

FIG. 5 illustrates a cross-sectional view showing a portion of an organic light-emitting display apparatus according to another embodiment;

FIG. 6 illustrates a portion of an organic light-emitting display apparatus according to another embodiment; and

FIGS. 7A-7D illustrate steps in a method of manufacturing an organic light-emitting display apparatus according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present.

The sizes of all elements shown in the drawings are randomly chosen, and thus, the lengths, widths, thickness, and all other dimensions of the elements shown in the drawings are not limited thereto. As used herein, the term “and/or” includes any and all combinations of one or more of the associated listed items. Expressions such as “at least one of,” when preceding a list of elements, modify the entire list of elements and do not modify the individual elements of the list.

In the following embodiments, the x-axis, y-axis, and z-axis are not limited to the three axes of a rectangular coordinate system, and may be construed broadly as meaning three random axes. For example, the x-axis, the y-axis, and the z-axis may be perpendicular to each other. However, they may have other directions without necessarily being perpendicular to each other.

The terms, first and second, as used herein, may be used to explain various features. However, the features are not limited by the terms used, and these terms are only used to distinguish one feature from another feature.

The terms as used herein are only used to explain specific embodiments and thus are not limiting. A singular expression includes a plural expression, unless clearly stated otherwise. In the present application, terms such as “including” or “having” are only used to specify the existence of characteristics, numbers, processes, operations, features, components, or a combination thereof, and should not be construed as to exclude the existence of one or more of other characteristics, numbers, processes, operations, features, components, or a combination thereof.

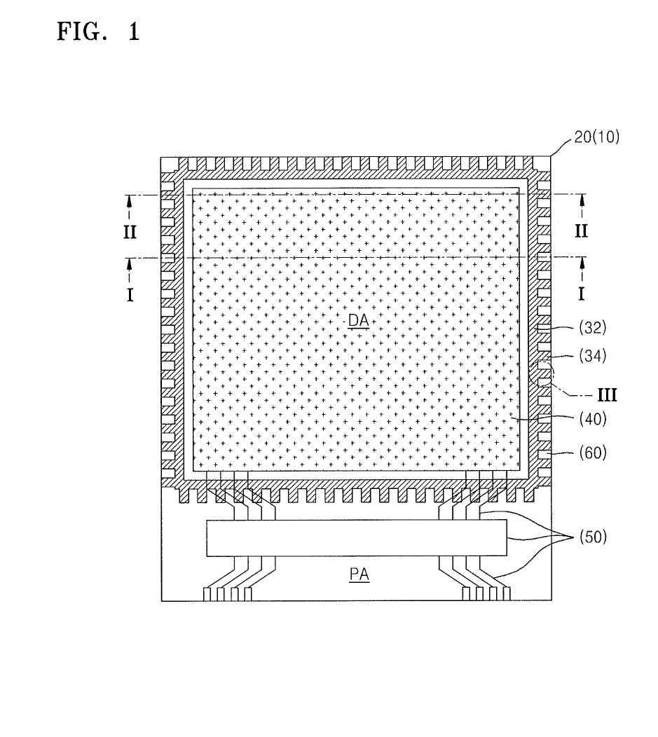

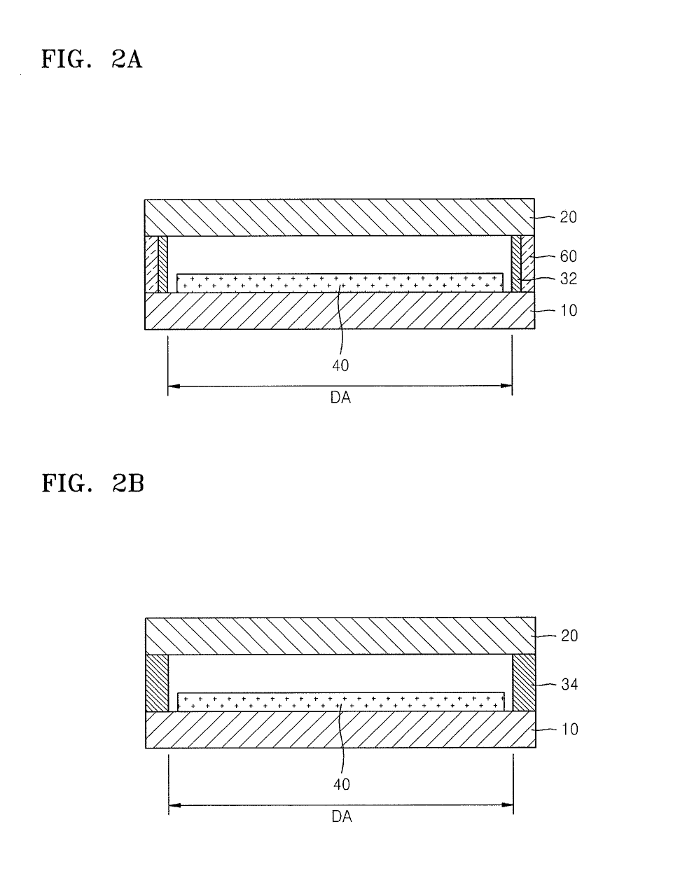

FIG. 1 illustrates a plane view of an organic light-emitting display apparatus according to an embodiment, FIG. 2A illustrates a cross-sectional view of I-I of FIG. 1, and FIG. 2B illustrates a cross-sectional view of II-II of FIG. 1.

Referring to FIGS. 1, 2A, and 2B, an organic light-emitting display apparatus may include a first substrate 10 including a display portion 40, a second substrate 20 disposed opposite the first substrate 10, a sealing line 32 that encloses the display portion 40 and binds the first substrate 10 to the second substrate 20, and a plurality of sealing branches 34 that bind the first substrate 10 and the second substrate 20. One end 34E1 of sealing branch 34 may contact the sealing line 32, and other end 34E2 may not contact the sealing line 32.

The first substrate 10 may be divided into a display area DA and a peripheral area PA enclosing the display area DA. The substrate 10 may be made of a transparent glass material including SiO2 as a main material. However, the substrate 10 is not limited thereto and may be made of a transparent plastic material. The substrate 10 may be a flexible substrate that may be manufactured by using a material that is lightweight due to smaller specific gravity than the glass substrate, does not break easily, and is bendable. For example, the material may be a polymer material such as a flexible plastic film.

The display portion 40 of the first substrate 10 may include a transistor TR, which is a thin film transistor for driving, a capacitor Cst, an organic light-emitting device OLED, or the like on the first substrate 10. The display portion 40 is described below in detail.

The second substrate 20 may be disposed opposite the first substrate 10, and the second substrate 20 may be made of various materials such as a glass material, a metal material, a plastic material, or the like. The first substrate 10 may be attached to the second substrate 20 with the sealing line 32 and the plurality of sealing branches 34. The sealing line 32 and the plurality of sealing branches 34 may be made of the same material. For example, the sealing line 32 and the plurality of sealing branches 34 may include glass frit or the like.

In greater detail, sealing line 32 may enclose the display portion 40 to separate the display area DA from the peripheral area PA. The sealing line 32 may seal the display portion 40 to protect the display portion 40 from outside. Also, one end 34E1 of the sealing branch 34 may contact the sealing line 32 and other end 34E2 may not contact the sealing line 32. For example, the other end 34E2 of the sealing line 32 may be exposed externally. When a display area DA is defined as an inner portion of the sealing line 32 and a peripheral area PA as an outer portion of the sealing line 32, the sealing branch 34 may be located at the outer portion of the sealing line 32 and the one end 34E1 may contact the sealing line 32.

An organic light-emitting display apparatus according to an embodiment may include the sealing branch 34 therein in addition to the sealing line 32 to broaden a contact area of the sealing line 32 with respect to the first and the second substrates. Furthermore, due to a broader contact area, adhesiveness between the first substrate 10 and the second substrate 20 may be increased. Although the sealing line 32 may be located in all areas except for a pad portion 50 to maximize the contact area, a crack may occur. As a result, the organic light-emitting display apparatus according to an embodiment may include the sealing branch 34 to broaden the contact area and prevent the occurrence of a crack.

The plurality of the sealing branches 34 may be separated from each other. Also, at least one of the plurality of sealing branches 34 may perpendicularly contact the sealing line 32. For example, a lengthwise direction of at least one of the plurality of sealing branches 34 may be perpendicular to a sealing line 32. FIG. 1 shows all of the plurality of sealing branches 34 perpendicularly contacting the sealing line 32. For example, some of the plurality of sealing branches 34 may be disposed perpendicularly to the sealing line 32 and other sealing branches 34 may be disposed at an inclined angle with respect to the sealing line 32. When the sealing branch 34 is disposed at an inclined angle with respect to the sealing line 32, the contact area of the sealing line 32 with respect to the first and the second substrates 10 and 20 may be enlarged.

A stiffener 60 that may supplement binding between the sealing branches 34 may be filled between two neighboring sealing branches 34 of the plurality of sealing branches 34. The stiffener 60 may include a resin, for example, a polymer resin. The stiffener 60 may supplement mechanical strength that has been deteriorated due to thermal shock and stress generated from a thermal mismatch between the glass fit of the sealing line 32 and glass of the first and the second substrates 10 and 20.

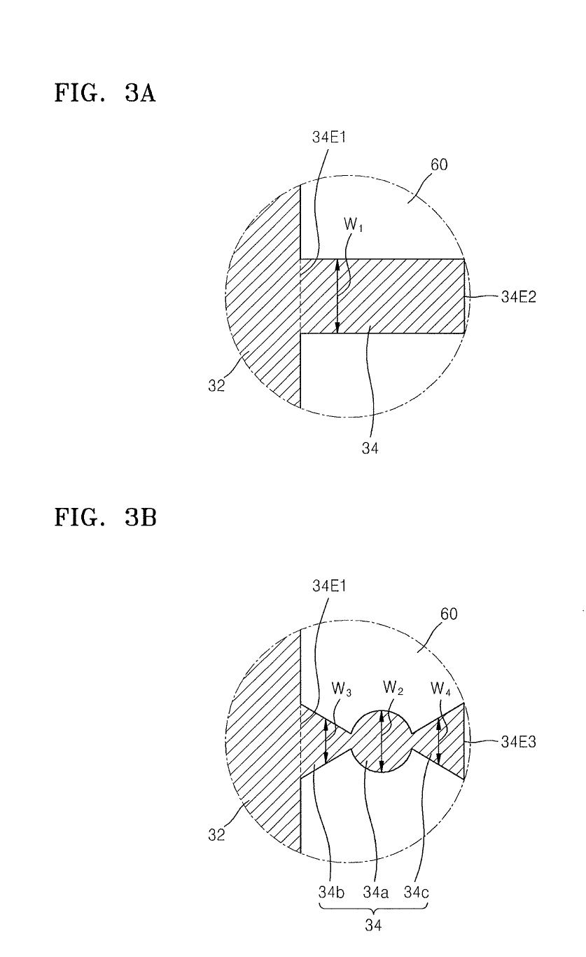

FIG. 3A to FIG. 3B illustrate plane views showing detailed shapes of the sealing branch shown in FIG. 1.

As illustrated in FIG. 3A, a width of the sealing branch 34 may be uniform. However, the width w1 of the sealing branch 34 may be non-uniform. For example, as illustrated in FIG. 3B, the sealing branch 34 may include a crack preventing portion 34a that prevents spreading of a crack generated at one end 34E2 to the other end 34E1 of the sealing branch 34. Also, the sealing branch 34 may further include a first sealing branch 34b that contacts the sealing line 32 at one end and the crack preventing portion 34a at the other end. The sealing branch 34 may also include a second sealing branch 34c that contacts the crack preventing portion 34a at one end and is externally exposed at the other end. FIG. 3B illustrates the first and the second sealing branches 34b and 34c, but is not limited thereto. In exemplary embodiments, only the first sealing branch 34b may be disposed in the sealing branch 34, or only the second sealing branch 34c may be disposed in the sealing branch 34. At least one of the first and the second sealing branches 34b and 34c may include an area that has a narrower width (w3 or w4) than a maximum width w2. For example, at least one of the first and the second sealing branches 34b and 34c may have a narrowest width in an area that contacts the crack preventing portion 34a.

As described below, the second sealing branch 34c may be produced by cutting. A crack may be generated in the second sealing branch 34c due to the cutting. However, most of the cracks generated in the second sealing branch 34c may disappear in the crack preventing portion 34a having a large volume. Even when the crack passes through the crack preventing portion 34a, the crack may not pass through an area that has a narrow width in the first sealing branch 34b, thereby reducing the possibility of spreading of the crack to the sealing line 32. As a result, the crack produced from the cutting may not spread to the sealing line 32, and thus, the sealing line 32 may stably protect the display portion 40 from external environment.

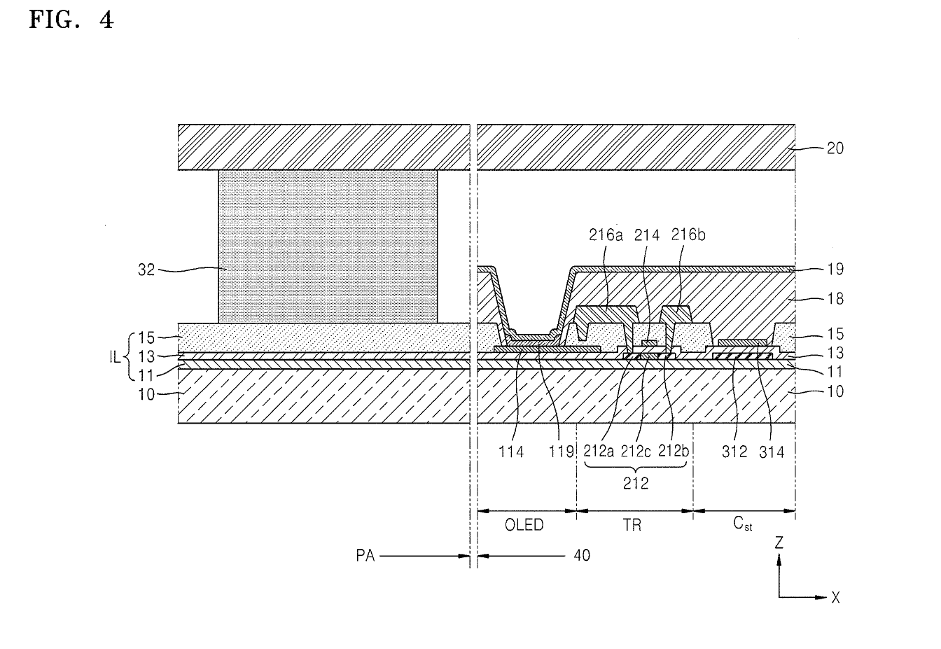

FIG. 4 illustrates the sealing line 32 and the display portion 40 shown in FIG. 1 in detail.

As illustrated in FIG. 4, a buffer layer 11 may be further provided on a first substrate 10. The buffer layer 11 may be made of an inorganic material such as SiOx, SiNx, SiON, AlO, or AlON, an organic material such as acryl or polyimide, or alternating layers of the organic material and the inorganic material. The buffer layer 11 may block oxygen and moisture, prevent diffusion of moisture or impurities generated from the substrate 10, and adjust a heat transfer speed of heat during crystallization so that a semiconductor may be satisfactorily crystallized.

Also, the display portion 40 of the first substrate 10 may include a transistor TR, a capacitor Cst, and an organic light-emitting device OLED on the substrate 10. In greater detail, the transistor TR may be formed on the buffer layer 11. The present embodiments illustrate a thin film transistor having a bottom gate form, but the thin film transistor may have another structure such as a top gate form or the like.

An active layer 212 may be formed on the buffer layer 11. When the active layer 212 is formed of polysilicon, the active layer 212 may be first formed of amorphous silicon, which is then crystallized into the polysilicon.

Methods of crystallizing the amorphous silicon include rapid thermal annealing (RTA), solid phase crystalization (SPC), eximer laser annealing (ELA), metal induced crystallization (MIC), metal induced lateral crystallization (MILC), and sequential lateral solidification (SLS). Methods may be used that do not require a high temperature heating process to use the substrate according to embodiments.

For example, during crystallization by using a low temperature poly-silicon (LTPS) process, the active layer 212 may be activated by irradiating a laser beam for a short period of time so as to prevent the first substrate 10 from being exposed to a high temperature equal to or higher than 300° C., and thus the entire processes may be performed at a temperature equal to or less than 300° C. Accordingly, the transistor TR may be formed by applying a substrate formed of a polymer material.

An N-type or a P-type impurity ion may be doped on the active layer 212 to form a source area 212b and a drain area 212a. An area between the source area 212b and the drain area 212a may be a channel area 212c on which the impurities are not doped.

A gate insulating film 13 may be formed on the active layer 212. The gate insulating film 13 may be formed as a single layer structure of SiO₂ or as a double layer structure of SiO₂ and SiNₓ.

A gate electrode 214 may be formed on a predetermined area of the gate insulating film 13. The gate electrode 214 may be connected to a gate line (not shown) which transmits a transistor on/off signal. The gate electrode 214 may be formed as a single layer or a plurality of conductive layers.

A drain electrode 216a and a source electrode 216b, which respectively connect to the drain area 212a source area 212b, may be formed on the gate electrode 214 with an interlayer insulating layer 15 disposed therebetween. The interlayer insulating layer 15 may be formed of an insulating material such as SiO₂ or SiNₓ, and may be formed of an insulating organic material.

A pixel defining layer 18 may be formed on the interlayer insulating layer 15 to cover the drain electrode 216a and the source electrode 216b. However, a pixel electrode 114 including the same transparent conductive material as the gate electrode 214 may be formed on the buffer layer 11 and the gate insulating film 13. A resistance of the drain electrode 216a and the source electrode 216b may be smaller than that of the gate electrode 214.

A metal having a low work function, in other words, Li, Ca, LiF/Ca, LiF/Al, Al, Mg, or a compound thereof, may be deposited on an intermediate layer 119, and then an auxiliary electrode including a material for forming a transparent electrode such as ITO, IZO, ZnO, or In₂O₃ may be formed thereon to manufacture the pixel electrode. However, the pixel electrode 114 is not limited thereto and may be a reflective electrode.

On the pixel electrode 114, a portion of the pixel defining layer 18 may be etched to form an intermediate layer 119. The intermediate layer 119 may include an emissive layer that may emit visible rays.

A counter electrode 19 may be formed as a common electrode on the intermediate layer 119. On the intermediate layer 119, voltages of different polarities may be applied such that light is emitted from the intermediate layer 119.

The emissive layer of the intermediate layer 119 may include a low molecular weight organic material or a high molecular weight organic material.

When a low molecular weight organic material is used for the emissive layer in the intermediate layer 119, the intermediate layer 119 may be formed as a single layer or a plurality of layers of hole injection layer (HIL), hole transport layer (HTL), emissive layer (EML), electron transport layer (ETL), and electron injection layer (EIL).

Also, an organic material that may be used for the intermediate layer 119 may include copper phthalocyanine (CuPc), N,N′-di(naphthalene-1-yl)-N,N′-diphenyl-benzidine, NPB), tris-8-hydroxyquinoline aluminum (Alq3), and the like. The low molecular weight material may be formed by using vacuum deposition or the like by using masks.

When the emissive layer of the intermediate layer 119 includes the high molecular weight organic material, the intermediate layer 119 may have a structure including the HTL and the EML. In this regard, PEDOT may be used for the HTL and poly-phenylenevinylene-based or polyfluorene-based high molecular weight organic material may be used for the EML. The high molecular weight organic material may be formed by a screen printing method or an inkjet printing method. However, the intermediate layer 119 is not limited thereto, and the intermediate layer 119 may have other structures.

The counter electrode 19 may be made of a transparent electrode or a reflective electrode as in the case of the pixel electrode 114. When the counter electrode 19 is used as a transparent electrode, a metal having a low work function, such as Li, Ca, LiF/Ca, LiF/Al, Al, Mg, or a compound thereof, may be deposited on an intermediate layer 119, and then an auxiliary electrode made of a material for forming a transparent electrode such as ITO, IZO, ZnO, or In₂O₃ may be formed thereon to manufacture the counter electrode 19.

When the counter electrode 19 is used as a reflective electrode, the counter electrode 19 may be formed by depositing Li, Ca, LiF/Ca, LiF/Al, Al, Mg, or a combination thereof on the intermediate layer 119.

Also, the pixel electrode 114 may be formed in a shape that corresponds to a shape of an opening of each sub pixel when the pixel electrode 114 is formed as a transparent electrode or a reflective electrode. The counter electrode 19 may be formed by depositing a transparent electrode or a reflective electrode throughout the display area DA. Alternatively, the counter electrode 19 may not be formed throughout the display area DA but may be patterned in any shape. In this regard, the pixel electrode 114 and the counter electrode 19 may be layered in opposite directions.

In the case of the organic light-emitting display apparatus according to embodiments, the pixel electrode 114 may be an anode, and the counter electrode 19 may be a cathode. The polarities of the electrodes may be reversed.

Also, the buffer layer 11, the gate insulating film 13, and the interlayer insulating layer 15, as a whole, may be referred to as an insulating layer IL. The insulating layer IL may be disposed on the display portion 40 of the first substrate 10 and peripheral area PA, for example, as illustrated in the drawings. Furthermore, the sealing line 32 may be disposed on the insulating layer IL to attach the first substrate 10 to the second substrate 20. Although not shown in the drawings, the sealing branch 34 may be disposed on the insulating layer IL to bind the first and the second substrates 10 and 20.

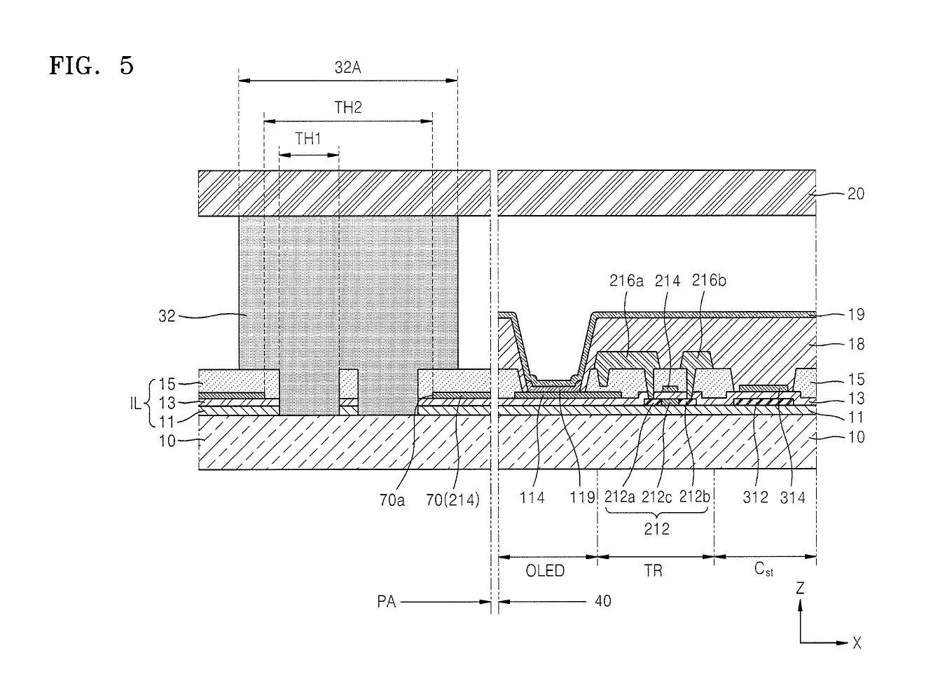

FIG. 5 illustrates a cross-sectional view showing a portion of an organic light-emitting display apparatus according to another embodiment. As illustrated in FIG. 5, the insulating layer IL may include at least one first through-hole TH1 in the peripheral area PA.

When the sealing line 32 attaches the first substrate 10 to the second substrate 20, a contact area may have a sufficient binding force. However, the greater the width 32A occupied by the sealing line 32, the greater the peripheral area PA, which is a dead space. As a result, to reduce the dead space, an area occupied by the sealing line 32, that is, the width 32A, may be reduced.

Also, the insulating layer IL may include at least one first through-hole TH1. Accordingly, the area of the sealing line 32 on a surface area that is parallel to the first substrate 10 (xy surface area) may be reduced while the sealing line 32 increases a contact area between components on the first substrate 10 and the insulating layer IL. Accordingly, the area occupied by the sealing line 32, that is, the width 32A may be reduced so as to reduce the dead space and maintain or increase the binding force between the sealing line 32 and the first substrate 10.

Also, as illustrated in FIG. 5, the organic light-emitting display apparatus may be disposed between the first substrate 10 and the insulating layer IL and may include a metal layer 70 including at least one second through-hole TH2. The display portion 40 may include a thin film transistor (TFT) including the gate electrode 214 as described above, wherein the metal layer 70 may include the same material as the gate electrode 214 of the TFT. In greater detail, the metal layer 70 may be disposed on the same layer as the gate electrode 214. For example, the metal layer 70 may be extended from the gate electrode 214.

FIG. 5 illustrates a case in which the metal layer 70 is disposed on the gate insulating film 13, as in the case of the gate electrode 214. In some cases, the metal layer 70 may include the same material as the drain electrode 216a or the source electrode 216b of the TFT and may be disposed on the same layer. In the description below it is considered that the metal layer 70 includes the same material as the gate electrode 214 and is disposed on the same layer.

When the sealing line 32 is used to bind the first substrate 10 and the second substrate 20, UV light, laser beam, or the like may be irradiated to cure the sealing line 32. In greater detail, UV light or laser beam may be irradiated to the sealing line 32 through the second substrate 20, and an irradiation efficiency of the UV light or laser beam may be increased by reflecting the UV light or the laser beam that passes through to the sealing line 32 by using the metal layer 70 located at the bottom of the sealing line 32, such that the UV light or the laser beam is directed back to the sealing line 32, thereby increasing the irradiation efficiency of the UV light or the laser beam.

Also, the area in which the sealing line 32 contacts the second substrate 20 may be easily observable through the second substrate 20 made of a transparent material. However, the area in which the sealing line 32 contacts the first substrate 10 may not be observable because of the metal layer 70, which is not transparent. Accordingly, as the sealing line 32 may include at least one second through-hole TH2, the contact area between the sealing line 32 and the first substrate 10 may be observable through the second through-hole TH2 of the metal layer 70. As a result, it may determined whether the contact area between the sealing line 32 and the second substrate 20 and/or the first substrate 10 is greater than a predetermined minimum area to easily observe the presence of sealing defects. Thus, an inner portion 70a of each second through-hole TH2 may be covered by the insulating layer IL, such that the second through-hole TH2 does not contact the sealing line 32. In FIG. 5, the metal layer 70 is covered by the interlayer insulating layer 15, such that the inner portion 70a of the second through-hole TH2 of the metal layer 70 does not contact the sealing line 32.

Also, the first through-hole TH1 may be formed inside the second through-hole TH2. For example, when at least one first through-hole TH1 is formed in the insulating layer IL, the buffer layer 11, the gate insulating film 13, and the interlayer insulating layer 15 may be simultaneously etched to form at least one first through-hole TH1. During this process, if the inner portion 70a of the second through-hole TH2 of the metal layer 70 is exposed by at least one first through-hole TH1, the metal layer 70 in which the second through-hole TH2 is already formed may be additionally etched, which may increase the surface area of the second through-hole TH2 of the metal layer 70. In order to prevent such an increase in surface area, insulating layer IL may cover the inner portion 70a of at least one second through-hole TH2 of the metal layer 70, thereby preventing contact between metal layer 70 and the sealing line 32.

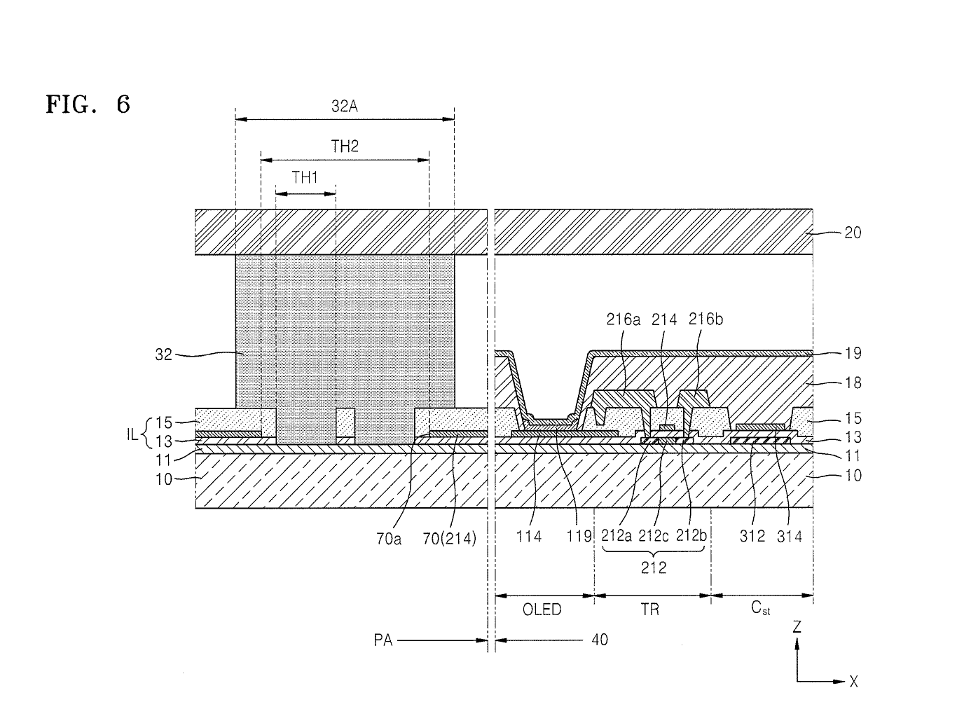

FIG. 6 illustrates a portion of an organic light-emitting display apparatus according to another embodiment. As illustrated in FIG. 6, the insulating layer IL may only includes the gate insulating film 13 and the interlayer insulating layer 15, and the buffer layer 11 may not include a through-hole. In this case, the buffer layer 11 may be an additional insulating layer disposed between the first substrate 10 and the insulating layer IL. As such, the insulating layer IL may be an extension of at least one of the buffer layer 11, the gate insulating film 13, and the interlayer insulating layer 15.

In FIGS. 4 to 6, the sealing line is shown as being disposed on the insulating layer IL or filling the first through-hole TH1 of the insulating layer IL. However, the present embodiment it is not limited thereto, and the sealing branch may also be disposed on the insulating layer IL or fill the first through-hole TH1 of the insulating layer IL.

A method of manufacturing an organic light-emitting display apparatus according to an embodiment will be described.

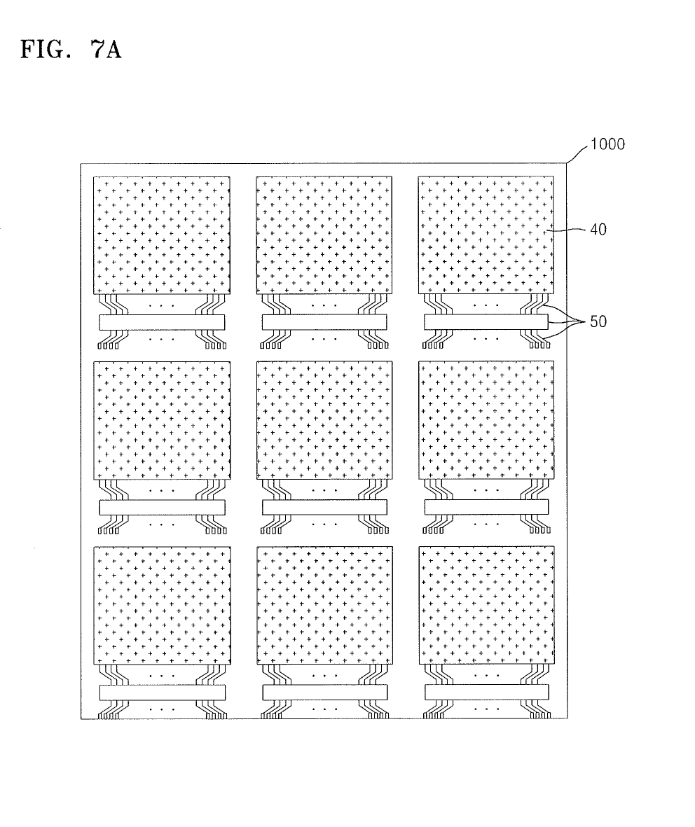

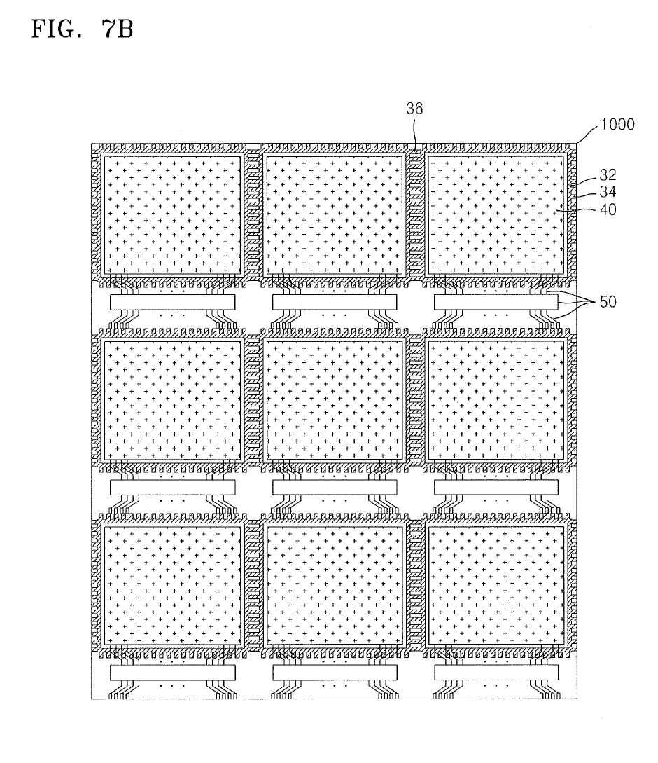

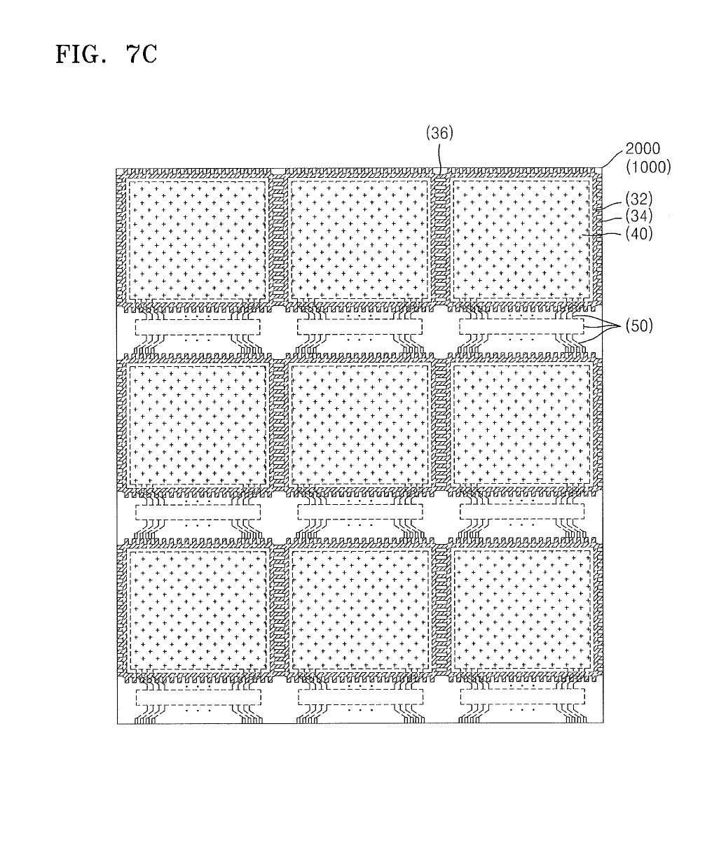

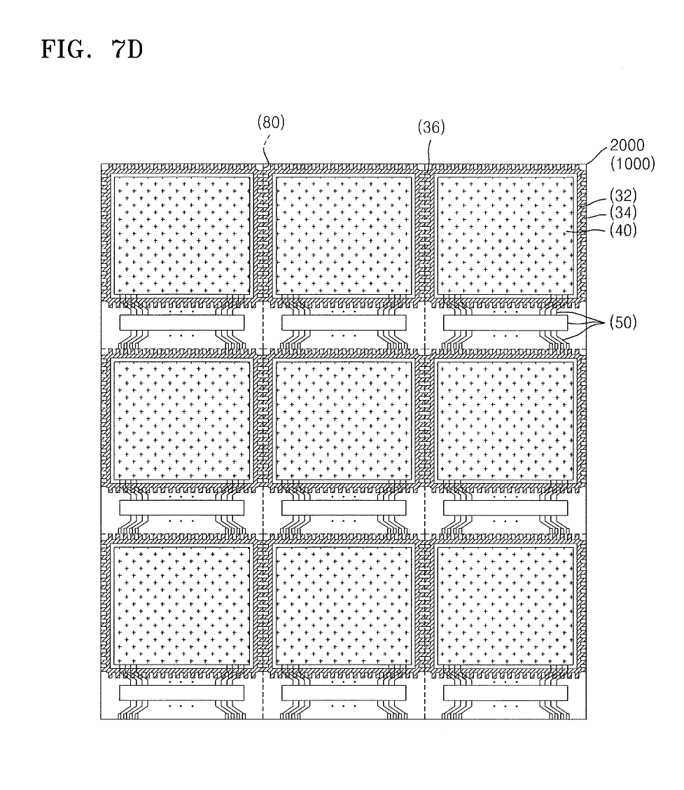

FIGS. 7A-7D illustrate steps of a method of manufacturing an organic light-emitting display apparatus according to an embodiment.

To manufacture an organic light-emitting display apparatus, first, a plurality of display portions 40 and a plurality of pad portions 50 may be formed on a first mother substrate 1000, as shown in FIG. 7a. An area that includes a portion where the display portion 40 is formed may be a display area DA and an area other than the display area DA may be a peripheral area PA.

Furthermore, as illustrated in FIG. 7b, the sealing line 32 may be formed to wrap each display portion 40, and a plurality of sealing bridges 36 may be formed to contact neighboring sealing lines 32, among the plurality of sealing lines 32. Also, one end of the sealing bridge 36 may be connected to the sealing line 32, and another end may form an externally exposed sealing branch 34. The sealing bridge 36 may become the sealing branch 34 by cutting. As a result, a material for the sealing bridge 36 may be the same as that of the sealing branch 34, and thus, a detailed description thereof will be omitted.

Thereafter, as illustrated in FIG. 7c, the sealing line 32, the sealing branch 34, and the sealing bridge 36 may be used to attach the first mother substrate 1000 to the second mother substrate 2000. Thereafter, when the first mother substrate 1000 is attached to the second mother substrate 2000, laser or UV light may be used to cure the sealing line 32, the sealing branch 34, and the sealing bridge 36.

As illustrated in FIG. 7d, the sealing bridge 36 may be cut to separate the plurality of display portions 40. When separating the display portions 40, the sealing branch 34 and the pad portion 50 may be cut as well. Each of the sealing bridges 36 that is cut may become the sealing branch 34. The cutting process may be performed with a scriber or laser. During the cutting process, an external pressure may be transmitted to the sealing bridge 36, and thus a crack may be generated in the sealing bridge 36. However, the crack may be prevented from spreading to the sealing line 32, and thus, cutting side effects may be minimized in the display portion 40.

By way of summation and review, an organic light-emitting display apparatus may be manufactured by forming a plurality of organic light-emitting devices and pads on a first mother substrate, attaching a second mother substrate to the first mother substrate with a sealing material, and then cutting the resultant structure. During the cutting operation, cracks may be generated in the first and second mother substrates.

In contrast, according to the one or more of the above embodiments, the organic light-emitting display apparatus may prevent spreading of a crack. Also, a contact area between the sealing line and the substrate may be enlarged to improve a binding force.

One or more embodiments include an organic light-emitting display apparatus having strong adhesiveness and a method of manufacturing the same. In addition, one or more embodiments include an organic light-emitting display apparatus that may prevent spreading of a crack that may occur in a cutting operation.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting display apparatus comprising:
a first substrate including a display portion;
a second substrate opposite the first substrate;
a sealing line enclosing the display portion and binding the first substrate to the second substrate; and
a plurality of sealing branches binding the first substrate to the second substrate,
wherein:
the plurality of sealing branches each includes a first end and a second end,
each first end contacts the sealing line, and
each second end does not contact the sealing line.

2. The organic light-emitting display apparatus as claimed in claim 1, wherein each second end is externally exposed.

3. The organic light-emitting display apparatus as claimed in claim 1, wherein the plurality of sealing branches are separated from each other.

4. The organic light-emitting display apparatus as claimed in claim 1, further comprising a stiffener between two neighboring sealing branches of the plurality of sealing branches,
wherein the stiffener supplements binding between the sealing branches.

5. The organic light-emitting display apparatus as claimed in claim 4, wherein the stiffener includes a polymer resin.

6. The organic light-emitting display apparatus as claimed in claim 1, wherein at least one sealing branch of the plurality of sealing branches perpendicularly contacts the sealing line.

7. The organic light-emitting display apparatus as claimed in claim 1, wherein at least one of the plurality of sealing branches has a uniform width.

8. The organic light-emitting display apparatus as claimed in claim 1, wherein at least one of the plurality of sealing branches has a non-uniform width.

9. The organic light-emitting display apparatus as claimed in claim 1, wherein at least one of the plurality of sealing branches includes a crack preventing portion configured to prevent a crack generated in the first end from spreading to the second end.

10. The organic light-emitting display apparatus as claimed in claim 9, wherein at least one of the plurality of sealing branches includes:
a first sealing branch that contacts the sealing line at the first end of the first sealing branch and contacts the crack preventing portion at the second end of the first sealing branch; and
a second sealing branch that contacts the crack preventing portion at the first end of the second sealing branch and is externally exposed at the second end of the second sealing branch.

11. The organic light-emitting display apparatus as claimed in claim 10, wherein at least one of the first and the second sealing branches includes an area that has a narrower width than a maximum width of the crack preventing portion.

12. The organic light-emitting display apparatus as claimed in claim 10, wherein at least one of the first and the second sealing branches has a narrowest width in an area that contacts the crack preventing portion.

13. The organic light-emitting display apparatus as claimed in claim 1, wherein the sealing line and the plurality of sealing branches include a same material.

14. The organic light-emitting display apparatus as claimed in claim 13, wherein the material includes glass frit.

15. The organic light-emitting display apparatus as claimed in claim 1, wherein the first substrate further includes a peripheral area that encloses the display portion,
wherein an insulating layer is over the display portion and the peripheral area on the first substrate, the insulating layer including at least one through-hole corresponding to the peripheral area.

16. The organic light-emitting display apparatus as claimed in claim 15, wherein the display portion includes a buffer layer, a gate insulating film, and an interlayer insulating layer, the insulating layer including at least one of the buffer layer, the gate insulating film, and the interlayer insulating layer.

17. The organic light-emitting display apparatus as claimed in claim 15, wherein the sealing line fills inside a first through-hole.

18. The organic light-emitting display apparatus as claimed in claim 17, wherein a metal layer is in the insulating layer and includes at least one second through-hole on the first substrate.

19. The organic light-emitting display apparatus as claimed in claim 18, wherein the first through-hole is in the second through-hole.

20. A method of manufacturing an organic light-emitting display apparatus comprising:
providing a first mother substrate comprising a plurality of display portions;
forming a plurality of sealing lines respectively enclosing a plurality of display portions and a plurality of sealing bridges connecting neighboring sealing lines among the plurality of sealing lines;
binding the first mother substrate to a second mother substrate with the plurality of sealing lines and the plurality of sealing bridges; and
cutting the plurality of sealing bridges to separate the plurality of display portions.
